(19) United States
(12) Patent Application Publication
(10) Pub. No.: US 2008/0230783 A1
(43) Pub. Date: Sep. 25, 2008

(54) Image Sensor and Method for Manufacturing the Same

(76) Inventor: Hyun Ju Lim, Mapo-gu (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 12/051,159

(22) Filed: Mar. 19, 2008

(30) Foreign Application Priority Data
Mar. 19, 2007 (KR) 10-2007-0026403

(51) Int. Cl. H01L 31/0352; H01L 21/02

(52) U.S. Cl. 257/59; 438/70; 257/E31.032; 257/E21.002

(57) ABSTRACT

An image sensor and a method for manufacturing the same are provided. The image sensor can include: a semiconductor substrate including a circuit area; a metal interconnection layer including a metal interconnection and a an interlayer dielectric layer on the semiconductor substrate; a first conductive-type pattern on the metal interconnection layer; an intrinsic layer pattern having a dome-like shape on the first conductive-type pattern; and a second conductive-type conductive layer on the metal interconnection layer including the intrinsic layer pattern.

### CROSS-REFERENCE TO RELATED APPLICATION

The present application claims the benefit under 35 U.S.C. §119 of Korean Patent Application No. 10-2007-0026403, filed Mar. 19, 2007, which is hereby incorporated by reference in its entirety.

### BACKGROUND

In general, an image sensor is a semiconductor device for converting optical images into electrical signals. The image sensor is mainly classified as a charge coupled device (CCD) image sensor or a complementary metal oxide silicon (CMOS) image sensor.

A CMOS image sensor includes a photodiode and a MOS transistor in each unit pixel and sequentially detects electric signals of each unit pixel in a switching manner to realize an image.

The photodiode region converts a light signal into an electrical signal, and the transistor processes the electrical signal. Generally, in a CMOS image sensor, the photodiode and the transistor are horizontally disposed on a semiconductor substrate.

According to a horizontal-type CMOS image sensor, a photodiode and a transistor are horizontally adjacent to each other on a semiconductor substrate. Therefore, an additional region on the substrate within each pixel is required for forming the photodiode.

### BRIEF SUMMARY

Embodiments of the present invention relate to an image sensor and a method for manufacturing the same, in which a transistor circuit and a photodiode can be vertically integrated.

According to an embodiment of the present invention, an image sensor can include: a semiconductor substrate including a circuit area; a metal interconnection layer including a metal interconnection and an interlayer dielectric layer on the semiconductor substrate; a first conductive-type pattern on the metal interconnection layer; an intrinsic layer pattern having a dome-like shape on the first conductive-type pattern; and a second conductive-type conductive layer on the metal interconnection layer including the intrinsic layer pattern.

According to an embodiment, a method for manufacturing an image sensor can include forming a metal interconnection layer including a metal interconnection and an interlayer dielectric layer on a semiconductor substrate including a circuit area; forming a first conductive-type pattern on the metal interconnection layer; forming an intrinsic layer pattern having a hemispherical or dome-like shape on the first conductive-type pattern; and forming a second conductive-type conductive layer on the metal interconnection layer including the intrinsic layer pattern.

The details of one or more embodiments are set forth in the accompanying drawings and the description below. Other features will be apparent from the description and drawings, and from the claims.

### BRIEF DESCRIPTION OF THE DRAWINGS

FIGS. 1 to 6 are cross-sectional views showing the manufacturing process of an image sensor according to an embodiment of the present invention.

### DETAILED DESCRIPTION OF THE EMBODIMENTS

Hereinafter, an image sensor and a method of fabricating the same will be described in detail with reference to the accompanying drawings. When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

FIG. 6 is a cross-sectional view showing an image sensor at a stage of the fabricating process according to an embodiment of the present invention.

Referring to FIG. 6, an image sensor can include a semiconductor substrate 100 having a circuit area (not shown) and a metal interconnection layer 220, including a metal interconnection 210 and an interlayer dielectric layer 200 disposed on the semiconductor substrate 100. A first conductive-type pattern 301 can be disposed on the metal interconnection layer 220, and an intrinsic layer pattern 401 having a convex or dome-like shape can be disposed on the first conductive pattern 301. A second conductive-type conductive layer 501 can be disposed on the metal interconnection layer 220 including the intrinsic layer pattern 401.

A plurality of metal interconnections 210 can be provided according to unit pixels.

In an embodiment, the first conductive-type pattern 301 can be disposed on the metal interconnection 210 such that the first conductive-type pattern 301 is connected to the metal interconnection 210. Additionally, the first conductive-type pattern 301 can be spaced apart from an adjacent first conductive-type pattern.

Since the first conductive-type pattern 301 can be disposed on the metal interconnection 210 spaced apart from an adjacent first conductive-type pattern, a photodiode formed from the first conductive-type pattern 301 can be provided on each pixel unit having some isolation. Accordingly, cross-talk and noise of the image sensor can be inhibited.

The intrinsic layer pattern 401 can be disposed on the first conductive-type pattern 301. In an embodiment, the intrinsic layer pattern 401 can be in contact with an adjacent intrinsic layer pattern. In an alternative embodiment, the intrinsic layer pattern 401 can be spaced apart from an adjacent intrinsic layer pattern. In addition, the intrinsic layer pattern 401 can surround the entire portion of the first conductive-type pattern 301, such that the first conductive-type pattern 301 is not exposed. According to embodiments of the present invention, the intrinsic layer pattern 401 can have a convex or dome-like shape.

The second conductive-type conductive layer 501 can be disposed on the metal interconnection layer 220 including the intrinsic layer pattern 401. Accordingly, the portion of the second conductive-type conductive layer 501 on the intrinsic layer pattern 401 can have a convex or dome-like shape.

In an image sensor according to an embodiment of the present invention, the focusing efficiency of incident light can be improved since a photodiode disposed on a metal interconnection 210 can have a convex or dome-like shape.

In addition, since the photodiode can have a convex or dome-like shape, the photodiode can act as a microlens. Thus, the manufacturing process can be simplified and manufacturing costs can be reduced since the process for forming a microlens can be omitted.

In one embodiment, the first conductive-type pattern 301 can be omitted and a bottom electrode (not shown) can be provided on each metal interconnection 210. In another embodiment, a bottom electrode can be provided below each first conductive-type pattern 301 to provide a larger surface area contact to the metal interconnection 210.

In an embodiment utilizing a bottom electrode (not shown), the bottom electrode can be formed of any suitable material known in the art, including chromium (Cr), titanium (Ti), titanium tungsten (TiW), or tantalum (Ta). In alternative embodiments, no bottom electrode is formed.

A top electrode 601 can be disposed on the second conductive-type conductive layer 501. The top electrode 601 can be a transparent electrode having good light transmittance and conductivity. The top electrode 601 can be formed of, for example, indium tin oxide (ITO) or cadmium tin oxide (CTO). Thereafter, a pattern process for the top electrode 601 can be performed. The portion of the top electrode 601 over the second conductive-type conductive layer 501 can have a convex or dome-like shape.

Additionally, a color filter array (not shown) can be disposed on the second conductive-type conductive layer 501 or the top electrode 601.

In an image sensor according to an embodiment of the present invention, a transistor circuit and a photodiode can be vertically integrated, leading to improved resolution and sensitivity.

Vertical integration of the transistor circuit and the photodiode can also improve a fill factor to close to 100%.

In addition, in an embodiment, photodiode unit pixels are spaced apart from each other, thereby inhibiting cross-talk between the pixels.

Furthermore, the photodiode can have a convex or dome-like shape, so that the focusing efficiency for light can be improved and a process for forming a microlens can be omitted.

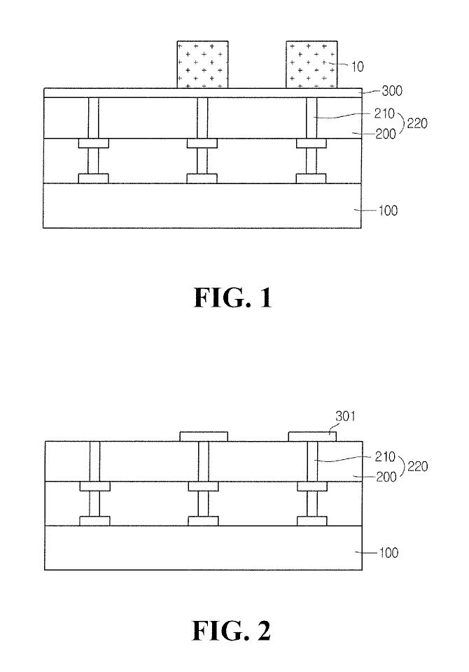

Hereinafter, a method for manufacturing an image sensor according to an embodiment will be described with reference to FIGS. 1 to 6.

Referring to FIG. 1, a metal interconnection layer 220, including a metal interconnection 210 and an interlayer dielectric layer 200, can be formed on a semiconductor substrate 100 including a circuit area (not shown).

Before forming the metal interconnection layer 220, an isolation layer (not shown) that defines an active area and a field area can be formed on the semiconductor substrate 100. The semiconductor substrate 100 can include a circuit area. In one embodiment, the circuit area can include a transfer transistor, a reset transistor, a drive transistor, and a select transistor for each unit pixel.

The metal interconnection layer 220 can be formed on the semiconductor substrate 100 to connect a power line or a signal line to the circuit area (not shown) of the semiconductor substrate 100. The metal interconnection layer 220 can include a plurality of metal interconnections 210 passing through the interlayer dielectric layer 200.

In an embodiment, a metal interconnection 210 can be formed in each unit pixel. The metal interconnection 210 can be formed of any suitable material known in the art, including various conductive materials such as metal, alloy, and silicide. For example, the metal interconnection 210 can be formed of aluminum, copper, cobalt, or tungsten.

A photodiode can be formed on the metal interconnection layer 220 such that the photodiode is electrically connected to the metal interconnection 210. In one embodiment, a bottom electrode (not shown) can be formed on the metal interconnection 210 before the photodiode is formed. The bottom electrode can be formed of, for example, Cr, Ti, TiW, or Ta. In alternative embodiments, the bottom electrode is not formed.

In the described embodiments, the photodiode formed on the metal interconnection layer 220 is a PIN diode. However, embodiments of the present invention are not limited thereto.

A PIN diode can be described as a diode with an intrinsic amorphous silicon layer between an n-type amorphous silicon layer and a p-type amorphous silicon layer. The performance of a photodiode depends on its charge capacitance and its efficiency in converting incident light into electrical signals. Typically, a photodiode generates and stores charges in a depletion region provided by a hetero-junction, such as P-N, N-P, N-P-N, and P-N-P, which are conventional photodiode structures used in horizontal-type CMOS image sensors. In contrast, because a PIN diode includes an intrinsic region, the entire intrinsic amorphous silicon layer between the n-type amorphous silicon layer and the p-type amorphous silicon layer can provide a depletion region. Therefore, in a PIN diode, electric charges are advantageously generated and stored as compared to a typical photodiode.

As described above, according to embodiments of the present invention, a PIN diode can be used as the photodiode. Though not expressly described in the subject disclosure, the PIN diode can be formed instead with a structure such as I-P or N-I-P. In the described embodiments, the first conductive-type conductive layer 300 can be n-type amorphous silicon serving as an N-layer of the PIN photodiode; the intrinsic layer 400 can be the intrinsic amorphous silicon layer of the PIN photodiode; and the second conductive-type conductive layer 501 can be p-type amorphous silicon serving as a P-layer of the PIN photodiode. Of course, embodiments are not limited thereto. For example, the first conductive type conduction layer 300 can be p-type amorphous silicon serving as a P-layer of an N-I-P photodiode, and the second conductive type conduction layer 501 can be n-type amorphous silicon serving as an N-layer of the N-I-P photodiode.

Hereinafter, a method of fabricating the photodiode will be described.

Referring again to FIG. 1, a first conductive-type conductive layer 300 can be formed on the metal interconnection layer 220.

The first conductive-type conductive layer 300 can be formed of any suitable material known in the art. For example, the first conductive-type conductive layer 300 can be formed of a-Si:H, a-SiGe:H, a-SiC, a-SiN:H, or a-SiO:H obtained by doping amorphous silicon with germanium, carbon, nitrogen, or oxygen.

The first conductive-type conductive layer 300 can be formed by any suitable process known in the art. For example, the first conductive-type conductive layer 300 can be formed through a chemical vapor deposition (CVD) process, particularly a plasma-enhanced chemical vapor deposition (PECVD) process. In an embodiment, the first conductive-type conductive layer 300 can be formed using amorphous silicon through a PECVD process by applying a mixture of silane gas (SiH₄) and PH₃ or P₂H₅.

The first conductive-type conductive layer 300 can be coated with a photoresist film, and a photoresist pattern 10 can be formed to cover an area of the first conductive-type conductive layer 300 over the metal interconnection 210, while exposing at least part of the remaining area of the first conductive-type conductive layer 300. The photoresist pattern 10 can be wider than the metal interconnection 210.

Referring to FIG. 2, a first conductive-type pattern 301 can be formed on the metal interconnection layer 220 such that the first conductive-type pattern 301 can be connected to the metal interconnection 210. The first conductive-type pattern 301 can be formed by etching the first conductive-type conductive layer 300 using the photoresist pattern 10 as an etching mask. Specifically, the first conductive-type conductive layer 300 exposed by the photoresist pattern 10 can be removed so that the first conductive-type pattern 301 may be formed on the metal interconnection 210. Thereafter, the photoresist pattern 10 can be removed.

The first conductive-type pattern 301 can be connected to the metal interconnection 210. In an embodiment, the first conductive-type pattern 301 can be separated from an adjacent first conductive-type pattern so a photodiode formed on the metal interconnection 210 can be separated from an adjacent photodiode.

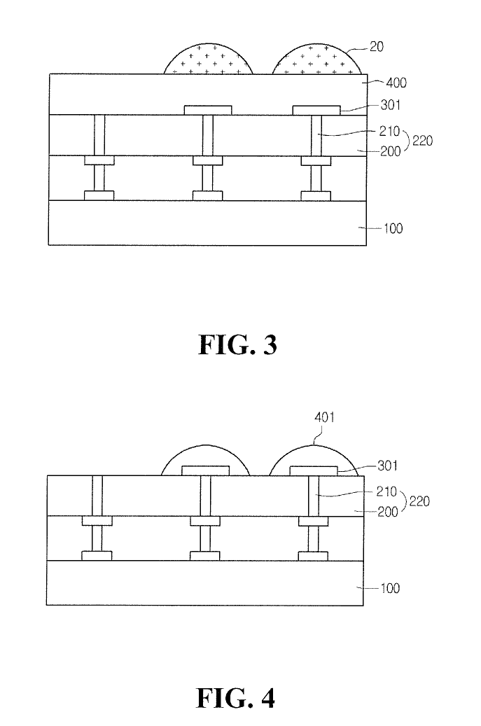

Referring to FIG. 3, an intrinsic layer 400 can be formed on the metal interconnection layer 220 including the first conductive-type pattern 301. In an embodiment, the intrinsic layer 400 can serve as an intrinsic (I) layer of a PIN photodiode.

The intrinsic layer 400 can be formed of, for example, intrinsic amorphous silicon. The intrinsic layer 400 can be formed by any suitable process known in the art, such as a CVD process, particularly a PECVD process. In an embodiment, the intrinsic layer 400 can be formed using intrinsic amorphous silicon through a PECVD process by applying SiH₄.

In an embodiment, the intrinsic layer 400 can have a thickness of about 10 times to about 1000 times thicker than that of the first conductive-type pattern 301. The intrinsic layer 400 can be thicker than the first conductive-type pattern 301 in order to expand the depletion area of a diode, allowing for greater storage and generation of optical charges.

Then, a microlens mask 20 can be formed on the intrinsic layer 400. The microlens mask 20 can be formed by coating a photoresist film is coated on the intrinsic layer 400, patterning the resist film, and performing a reflow process. Accordingly, the microlens mask 20 can have a convex or dome-like shape. In an embodiment, the microlens mask 20 can be wider than the first conductive-type pattern 301. Thus, the microlens mask 20 can either make contact with or be spaced apart from an adjacent microlens mask. In the described embodiments, the microlens masks 20 are spaced apart from each other, but embodiments of the present invention are not limited thereto.

Referring to FIG. 4, the intrinsic layer pattern 401 can be formed by etching the intrinsic layer 400 using the microlens mask 20 as an etching mask. The intrinsic layer pattern 401 can have a convex or dome-like shape and can be spaced apart from an adjacent intrinsic layer pattern. In an embodiment, the intrinsic pattern 401 can cover the entire outer peripheral surface of the first conductive-type pattern 301.

In the etching process of the intrinsic layer 400, the microlens mask 20 and the intrinsic layer 400 can be etched at an etching selectivity of 1 to 1. Thus, the etching process for forming the intrinsic layer pattern 401 with a convex or dome-like shape can be performed until all portions of a photoresist film forming the microlens mask 20 are etched.

The intrinsic layer pattern 401 can have the same convex or dome-like shape as that of the microlens mask 20. In embodiments where the microlens mask 20 is wider than the first conductive-type pattern 301, the intrinsic pattern 401 does not expose the first conductive-type pattern 301.

Since the first conductive-type pattern 301 and the intrinsic layer pattern 401 of the photodiode can be provided corresponding to each unit pixel, it is possible to inhibit cross-talk of an image sensor formed according to an embodiment of the present invention.

In addition, since the intrinsic layer pattern 401 can have the same convex or dome-like shape as that of a microlens, the focusing efficiency of the image sensor can be improved.

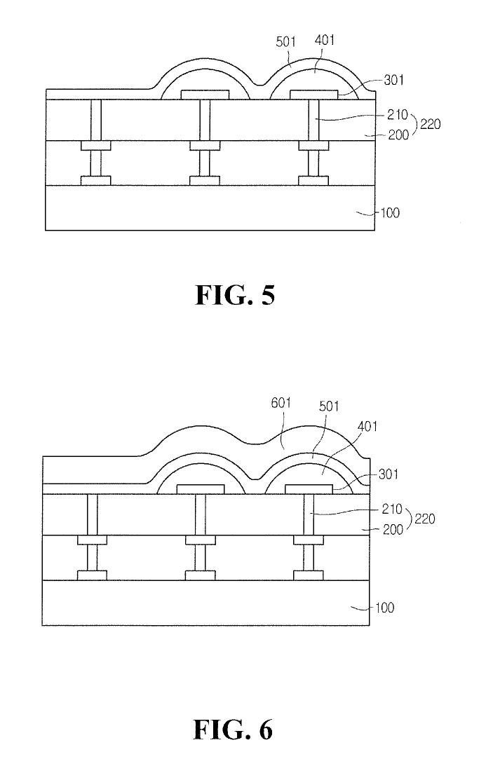

Referring to FIG. 5, a second conductive-type conductive layer 501 can be formed on the metal interconnection layer 220 including the intrinsic layer pattern 401.

The second conductive-type conductive layer 501 can be formed by any suitable process known in the art. For example, the second conductive-type conductive layer 501 can be formed through a CVD process, particularly a PECVD process. In an embodiment, the second conductive-type conductive layer 501 can be formed using amorphous silicon through a PECVD process by applying a mixture of SiH₄ and BH₃ or B₂H₆.

Since the second conductive-type conductive layer 501 can be formed on the metal interconnection layer 220 including the intrinsic layer pattern 401 having a convex or dome-like shape, the entire shape of the second conductive-type conductive layer 501 can be a wave-like. Thus, portions of the second conductive-type conductive layer 501 over the intrinsic layer pattern 401 can have a convex or dome-like shape, and certain remaining areas of the second conductive-type conductive layer 501 can have a concave shape.

According to an embodiment of the present invention, a photodiode having a PIN structure can be formed on the semiconductor substrate 100, allowing a transistor circuit to be vertically integrated with the photodiode. Accordingly, the fill factor of the photodiode can approach 100%. While a photodiode having a PIN structure has been described herein, embodiments of the present invention are not limited thereto.

In addition, since the photodiode can have the same convex or dome-like shape as that of a microlens, the focusing efficiency for light can be improved, allowing for the omission of the process of forming a microlens.

Referring to FIG. 6, a top electrode 601 can be formed on the second conductive-type conductive layer 501.

The top electrode 601 can be a transparent electrode having good light transmittance and conductivity. For example, the top electrode 601 can be indium tin oxide (ITO) or cadmium tin oxide (CTO). Thereafter, a pattern process for the top electrode 601 can be performed.

In an image sensor and a method for manufacturing the same according to embodiments of the present invention, a transistor circuit can be vertically integrated with a photodiode. This allows the fill factor of the photodiode to approach 100%.

Furthermore, according to embodiments of the present invention, sensitivity higher than that of the conventional technology can be obtained on the same pixel size through the use of vertical integration.

Additionally, manufacturing costs can be reduced while providing the same resolution.

Moreover, more complicated circuits can be provided in each unit pixel without the reduction of sensitivity.

In embodiments of the present invention, a vertical-type photodiode is employed including certain isolation techniques between unit pixels, thereby inhibiting cross-talk between the pixels and improving the reliability of the image sensor.

Since the vertical-type photodiode has a convex or dome-like shape, the focusing efficiency for light can be improved. Thus, it is unnecessary to form an additional microlens, leading to a simplified manufacturing process and lower manufacturing costs.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor, comprising:
a semiconductor substrate including a circuit area;
a metal interconnection layer comprising a metal interconnection layer and an interlayer dielectric layer on the semiconductor substrate;
an intrinsic layer pattern having a dome-like shape on the metal interconnection; and
a second conductive-type conductive layer on the metal interconnection layer including the intrinsic layer pattern.

2. The image sensor according to claim 1, further comprising a first conductive-type pattern on the metal interconnection layer below the intrinsic layer pattern.

3. The image sensor according to claim 2, wherein the first conductive pattern is connected to the metal interconnection.

4. The image sensor according to claim 2, wherein the intrinsic layer pattern surrounds an outer peripheral surface of the first conductive-type pattern.

5. The image sensor according to claim 2, wherein the first conductive-type pattern is one of a plurality of first conductive-type patterns on the metal interconnection layer; and wherein each first conductive-type pattern of the plurality of first conductive-type patterns is spaced apart from each adjacent first conductive-type pattern of the plurality of first conductive-type patterns.

6. The image sensor according to claim 1, wherein the intrinsic layer pattern is one of a plurality of intrinsic layer patterns; and wherein each intrinsic layer pattern of the plurality of intrinsic layer patterns is spaced apart from an adjacent intrinsic layer pattern of the plurality of intrinsic layer patterns.

7. The image sensor according to claim 1, wherein the intrinsic layer pattern is one of a plurality of intrinsic layer patterns; and wherein each intrinsic layer pattern of the plurality of intrinsic layer patterns makes contact with an adjacent intrinsic layer pattern of the plurality of intrinsic layer patterns.

8. The image sensor according to claim 1, wherein a portion of the second conductive-type conductive layer on the intrinsic layer pattern has a dome-like shape.

9. The image sensor according to claim 1, further comprising a bottom electrode on the metal interconnection.

10. The image sensor according to claim 1, further comprising a top electrode on the second conductive-type conductive layer.

11. The image sensor according to claim 10, further comprising a color filter on the second conductive-type conductive layer or the top electrode.

12. A method for manufacturing an image sensor, comprising:
forming a metal interconnection layer including a metal interconnection and an interlayer dielectric layer on a semiconductor substrate including a circuit area;
forming an intrinsic layer pattern having a dome-like shape on the metal interconnection layer; and
forming a second conductive-type conductive layer on the metal interconnection layer including the intrinsic layer pattern.

13. The method according to claim 12, further comprising forming a first conductive-type pattern on the metal interconnection layer before forming the intrinsic layer pattern.

14. The method according to claim 13, wherein forming the first conductive-type pattern comprises:
forming a first conductive-type conductive layer on the metal interconnection layer;
forming a photoresist pattern on a portion of the first conductive-type conductive layer over the metal interconnection; and
etching the first conductive-type conductive layer using the photoresist pattern as an etch mask.

15. The method according to claim 13, wherein the intrinsic layer pattern surrounds an outer peripheral surface of the first conductive-type pattern.

16. The image sensor according to claim 12, wherein forming the intrinsic layer pattern comprises:
forming an intrinsic layer on the metal interconnection layer;
forming a microlens mask having a dome-like shape on the intrinsic layer; and
etching the intrinsic layer using the microlens mask as an etching mask.

17. The method according to claim 12, wherein a portion of the second conductive-type conductive layer on the intrinsic layer pattern has a dome-like shape.

18. The method according to claim 12, further comprising forming a bottom electrode on the metal interconnection before forming the intrinsic layer pattern.

19. The method according to claim 12, further comprising forming a top electrode on the second conductive-type conductive layer.

20. The method according to claim 19, further comprising forming a color filter on the second conductive-type conductive layer or the top electrode.
